(19) United States
(12) Patent Application Publication
(10) Pub. No.: US 2021/0349393 A1
(43) Pub. Date: Nov. 11, 2021

(54) METHOD FOR IMPROVING UNIFORMITY OF PHOTORESIST DEVELOPMENT

(71) Applicant: CHANGXIN MEMORY TECHNOLOGIES, INC., Hefei City (CN)

(72) Inventor: Lei WANG, Hefei (CN)

(73) Assignee: CHANGXIN MEMORY TECHNOLOGIES, INC., Hefei City (CN)

(21) Appl. No.: 17/385,290

(22) Filed: Jul. 26, 2021

Related U.S. Application Data
(63) Continuation of application No. PCT/CN2021/079543, filed on Mar. 8, 2021.

(30) Foreign Application Priority Data
Mar. 11, 2020 (CN) 202010166105.X

(51) Int. Cl. G03F 7/30; G03F 7/42; G03F 7/09; G03F 7/32; G03F 7/20

(52) U.S. Cl. CPC G03F 7/3021; G03F 7/422; G03F 7/70808; G03F 7/322; G03F 7/09

(57) ABSTRACT

A method for improving uniformity of photoresist development includes: a substrate is provided, which is coated with a photoresist layer and includes a first area and a second area around a periphery of the first area; a second developer solution is transmitted to the second area, and the photoresist layer located in the second area is developed; a first developer solution is transmitted to the first area, and the photoresist layer located in the first area is developed.

### CROSS-REFERENCE TO RELATED APPLICATIONS

This application a continuation application of International Application No. PCT/CN2021/079543 filed on Mar. 8, 2021, which claims priority to Chinese Patent Application No. 202010166105.X filed on Mar. 11, 2020. The disclosures of these applications are hereby incorporated by reference in their entirety.

### BACKGROUND

At present, the industry of semiconductor Integrated Circuit (IC) has experienced exponential growth. Technological advances in IC materials and design have resulted in several generations of ICs, each generation of IC with smaller and more complex circuits than its predecessor. Over the course of IC development, functional density (that is, the number of interconnected devices per chip area) has generally increased, while geometric size (that is, the smallest component that can be produced using a manufacturing process) has decreased. In addition to IC components becoming smaller and more complex, wafers on which ICs are made are becoming larger and larger, which makes ever higher demands on wafer quality.

### SUMMARY

The present disclosure relates to the technical field of semiconductor manufacturing, and more specifically to a method for improving uniformity of photoresist development.

Various embodiments of the disclosure provide a method for improving uniformity of photoresist development for solving problems of uneven development in different areas of a photoresist and residual photoresist after development, so as to optimize a semiconductor manufacturing process and improve performance of a semiconductor structure.

More specifically, the disclosure provides the method for improving the uniformity of the photoresist development, including the following steps.

A substrate is provided. A surface of the substrate is coated with a photoresist layer, and the photoresist layer includes a first area and a second area around a periphery of the first area.

A second developer solution is transmitted to the second area, and the photoresist layer located in the second area is developed.

A first developer solution is transmitted to the first area, and the photoresist layer located in the first area is developed.

Optionally, before transmitting the second developer solution to the second area, the method further includes the following step.

The second area is cleaned.

Optionally, cleaning the second area includes the following specific steps.

A second nozzle is provided, and a spout of the second nozzle is moved to a position above the second area.

The second nozzle is controlled to spray a cleaning agent to the second area to enable the cleaning agent to cover the photoresist layer located in the second area while driving the substrate to rotate around an axis of the substrate.

Optionally, the cleaning agent is deionized water.

Optionally, developing the photoresist layer located in the second area includes the following specific step.

The photoresist layer located in the second area is completely removed or is partially removed.

Optionally, the method further includes the following steps.

A first nozzle is provided for spraying the first and the second developer solutions.

The first nozzle is controlled to spray a second dose of the second developer solution to the second area, and the photoresist layer located in the second area is developed.

The first nozzle is controlled to spray a first dose of the first developer solution to the first area, and the photoresist layer located in the first area is developed. The first dose is larger than the second dose.

Optionally, the first nozzle sprays the second developer solution to the second area at a second flow rate for a second period.

The first nozzle sprays the first developer solution to the first area at a first flow rate for a first period, the first flow rate is larger than the second flow rate, and the first period is longer than the second period.

Optionally, the first nozzle sprays the second developer solution to the second area at a second flow rate for a second period.

The first nozzle sprays the first developer solution to the first area at a first flow rate for a first period, the first flow rate is larger than the second flow rate, or the first period is longer than the second period.

Optionally, the first flow rate is 100 ml/min to 150 ml/min, and the second flow rate is 90 ml/min to 110 ml/min.

Optionally, a developing ability of the first developer solution is greater than a developing ability of the second developer solution.

Optionally, the first developer solution is of a same type as the second developer solution.

Optionally, the method further includes the following steps.

The substrate is driven to rotate around an axis thereof at a second rotating speed while transmitting the second developer solution to the second area.

The substrate is driven to rotate around the axis thereof at a first rotating speed while transmitting the first developer solution to the first area. The first rotating speed is larger than the second rotating speed.

Optionally, the second rotating speed is 50 rpm to 200 rpm, and the first rotating speed is 100 rpm to 300 rpm.

Optionally, after developing the photoresist layer located in the first area, the method further includes the following steps.

A cleaning fluid is transmitted to a center of the first area, simultaneously the substrate is driven to rotate around the axis thereof, and the first and the second developer solutions remaining on a surface of the photoresist layer are removed.

Optionally, during transmitting the cleaning fluid to the center of the first area, the substrate rotates around the axis thereof at a third rotating speed and the third rotating speed is larger than the first rotating speed.

Optionally, the third rotating speed is 500 rpm to 1000 rpm.

Optionally, after removing the developer solution(s) remaining on the surface of the photoresist layer, the method further includes the following steps.

The substrate is driven to rotate around the axis thereof at a fourth rotating speed, and the cleaning fluid remaining on the surface of the substrate is removed. The fourth rotating speed is larger than the third rotating speed.

Optionally, the first area is located at a center of the photoresist layer.

The second area is located at an edge of the photoresist layer and around the periphery of the first area.

Optionally, the first area has a circular shape, and the second area has an annular shape surrounding the first area.

A distance between an edge on a side of the second area towards the first area and a center of the first area is 80 mm to 120 mm.

For solving the above problems, the disclosure further provides a method for improving the uniformity of the photoresist development, including the following steps.

A substrate is provided. A surface of the substrate is coated with a photoresist layer. The photoresist layer includes N areas, an area located at a center of the photoresist layer is a first area having a circular shape, remaining (N−1) areas have annular shapes. The (N−1) annular areas are successively arranged along a direction from the center of the photoresist layer to an edge of the photoresist layer, and N is a positive integer greater than or equal to 3.

The (N−1) annular areas are developed successively along a direction from the edge of the photoresist layer to the center of the photoresist layer.

A developer solution is sprayed to the center of the first area, and the photoresist layer of the first area is developed.

According to the method for improving uniformity of photoresist development provided by the disclosure, through two development steps of firstly developing an edge area of the photoresist layer and then developing a center area of the photoresist layer, the problem of incomplete edge development caused by reduction of the developing ability in the process when the developer solution flows from the center to the edge is avoided. The uniformity of overall development of the photoresist layer is ensured. Residuals of the photoresist layer in the edge area are avoided, therefore a smooth progress of subsequent manufacturing processes is ensured, and the performance of the semiconductor structure is improved.

### BRIEF DESCRIPTION OF THE DRAWINGS

FIG. 1 is a flow diagram of a method for improving uniformity of photoresist development according to some embodiments of the disclosure.

FIG. 2A is a first schematic diagram of a process during development of a photoresist layer according to some embodiments of the disclosure.

FIG. 2B is a second schematic diagram of a process during development of a photoresist layer according to some embodiments of the disclosure.

FIG. 2C is a third schematic diagram of a process during development of a photoresist layer according to some embodiments of the disclosure.

FIG. 2D is a fourth schematic diagram of a process during development of a photoresist layer according to some embodiments of the disclosure.

FIG. 2E is a fifth schematic diagram of a process during development of a photoresist layer according to some embodiments of the disclosure.

FIG. 2F is a sixth schematic diagram of a process during development of a photoresist layer according to some embodiments of the disclosure.

### DETAILED DESCRIPTION

Photolithography is an important step in a manufacturing process of semiconductor devices such as Dynamic Random-Access Memory (DRAM). In a development process, for photoresist that coats an entire surface of the wafer, a developer solution is sprayed from a position corresponding to a center of the wafer. During a process that the developer solution flows from the center of the wafer to an edge, due to contact with the photoresist, a development activity decreases continuously, resulting a difference in activities between developer solution at the center of the wafer and that at the edge of the wafer, that is, a developing ability of the developer solution at the center of the wafer is greater than that at the edge of the wafer. The different developing ability of the developer solution at different positions on the surface of the wafer will lead to residual photoresist on the surface of the wafer after development, that is, incomplete development. Residual development will affect smooth implementation of subsequent processes, result in defects of a semiconductor structure eventually formed, or even lead to scraping of the wafer as a whole in serious cases.

Various embodiments of the present disclosure can address how to improve uniformity of wafer surface development, reduce or even avoid the residual photoresist at the wafer edge after development, so as to improve performance of the semiconductor structure.

The following is a detailed description of a specific example of a method for improving uniformity of photoresist development provided by the disclosure in combination with accompanying drawings.

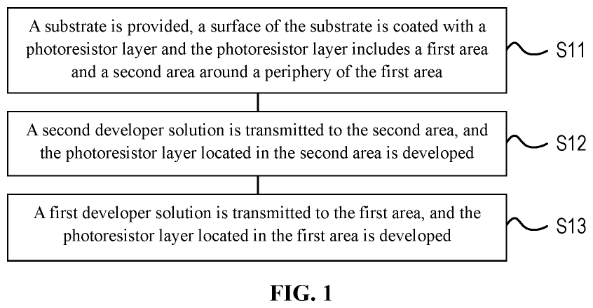

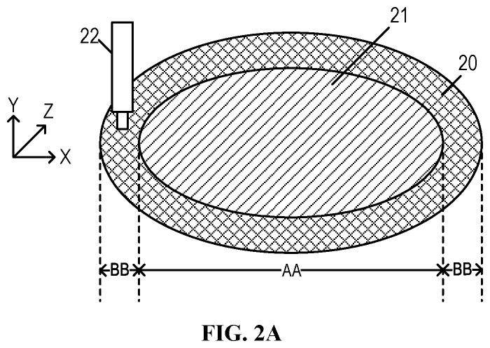

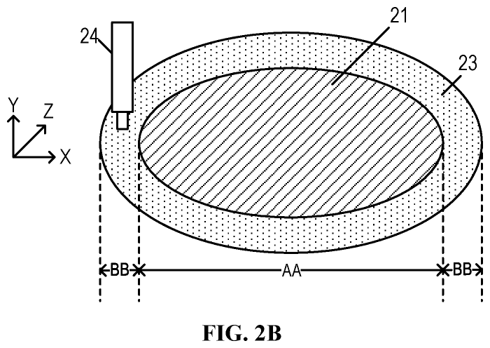

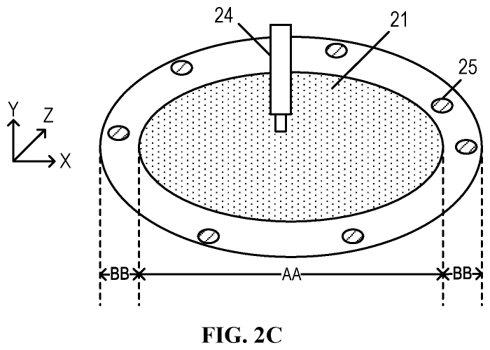

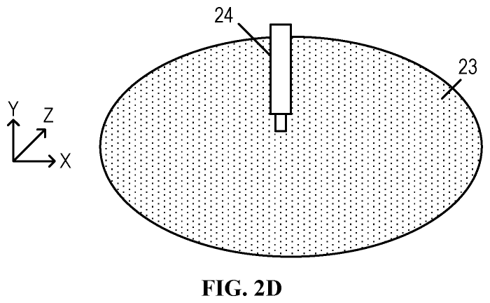

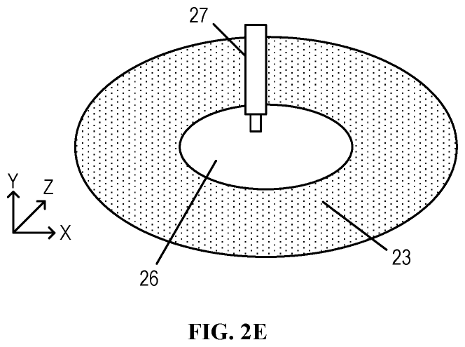

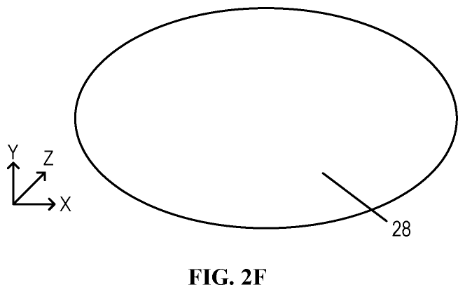

The specific example provides a method for improving uniformity of photoresist development. FIG. 1 is a flow diagram of a method for improving uniformity of photoresist development according to a specific example of the disclosure. FIG. 2A to 2F are schematic diagrams of main processes during development of a photoresist layer according to a specific example of the disclosure. As shown in FIGS. 1, 2A to 2F, the method for improving uniformity of photoresist development provided by the specific example includes the following steps.

At S11, a substrate is provided. A surface of the substrate is coated with a photoresist layer 21 which includes a first area AA and a second area BB distributed around a periphery of the first area AA. After exposing the photoresist layer, the situation is shown in FIG. 2A.

Optionally, the first area AA is located at a center of the photoresist layer 21.

The second area BB is located at an edge of the photoresist layer 21 and around the periphery of the first area AA.

Specifically, the substrate may be a partial area of a semiconductor wafer. In an exposure-development process, a photoresist material for forming the photoresist layer 21 may be coated on only a partial area of the surface of the substrate or on an entire surface of the substrate as required. In the specific example, the photoresist layer 21 needs to be removed as a whole in the exposure-development process. In other specific examples, the photoresist layer in a partially specified area may be exposed for development. In the specific example, illustration is made by taking the photoresist layer 21 that is coated on the entire surface of the substrate as an example (as the photoresist layer 21 is coated over the entire surface of the substrate, the substrate is not visible at an angle shown in FIG. 2A). The photoresist layer 21 includes the first area AA located at the center of the photoresist layer 21 and the second area BB located at the edge of the photoresist layer 21 and around the periphery of the first area AA. An exposure is made to the photoresist layer 21. Relative sizes and respective shapes of the first area AA and the second area BB may be selected by those of skill in the art according to actual needs. For example, a material of the photoresist layer 21, a type of a developer solution used in subsequent development processes, etc., are not restricted by the specific example.

At S12, a developer solution 23 is transmitted to the second area BB, and the photoresist layer 21 located in the second area BB is developed, as shown in FIG. 2B.

Optionally, before transmitting the developer solution 23 to the second area BB, the method further includes the following step.

The second area BB is cleaned.

Optionally, specific steps of cleaning the second area BB include the following steps.

A second nozzle 22 is provided, and a spout of the second nozzle 22 is moved to a position above the second area BB.

The second nozzle 22 is controlled to spray a cleaning agent to the second area BB while driving the substrate to rotate around an axis of the substrate to enable the cleaning agent to cover the photoresist layer located in the second area BB.

Specifically, in order to prevent interference of impurities that may exist in the second area BB to the development process, in the specific example, the second area BB may also be cleaned with the cleaning agent before the photoresist layer 21 of the second area BB is developed. For example, specific cleaning process may be as follows. First, the second nozzle 22 for spraying the cleaning agent is provided, and a spout of the second nozzle 22 is moved to the position above the second area BB. And then, the second nozzle 22 is controlled to spray the cleaning agent 20 to the second area BB while driving the substrate to rotate around the axis of the substrate to enable the cleaning agent 20 to cover the photoresist layer 21 located in the second area BB. In a cleaning process, the rotation of the substrate drives the photoresist layer 21 on it rotating. Due to an action of centrifugal force, the cleaning agent will be thrown out from the edge of the photoresist layer 21 instead of flowing to the first area AA. When cleaning the second area BB, a rotating speed of the substrate may be 100 rpm to 500 rpm, and a cleaning time of the cleaning agent 20 for the second area BB may last 2 s to 5 s. The axis of the substrate is a straight line that passes through a center of the substrate and extends in a direction perpendicular to the substrate (e.g., Z-axis direction in FIG. 2A).

Optionally, the cleaning agent is deionized water.

A specific type of the cleaning agent 20 may also be selected by those of skill in the art according to actual needs. In the specific example, in order to avoid affecting the subsequent processes, the cleaning agent 20 cleaning the second area BB may be the deionized water. Using the deionized water as the cleaning agent 20 cleaning the second area BB may not only realize cleaning, but can also pre-wet the second area BB so as to facilitate attachment of the developer solution to the second area BB subsequently.

At S13, the developer solution 23 is transmitted to the first area AA, and the photoresist layer 23 located in the first area AA is developed, as shown in FIG. 2C.

Optionally, the method for improving uniformity of photoresist development further includes the following steps.

A first nozzle 24 for spraying the developer solution 23 is provided;

The first nozzle 24 is controlled to spray a second dose of the developer solution 23 to the second area BB, and the photoresist layer 21 located in the second area BB is developed, as shown in FIG. 2B.

The first nozzle 24 is controlled to spray a first dose of the developer solution 23 to the first area AA, and the photoresist layer 21 located in the first area AA is developed. The first dose is larger than the second dose, as shown in FIG. 2C.

Optionally, the first nozzle 24 sprays the developer solution 23 to the second area BB at a second flow rate for a second period.

The first nozzle 24 sprays the developer solution 23 to the first area AA at a first flow rate for a first period, the first flow rate is larger than the second flow rate, and the first period is longer than the second period.

Optionally, the first nozzle 24 sprays the developer solution 23 to the second area BB at a second flow rate for a second period; and

The first nozzle 24 sprays the developer solution 23 to the first area AA at a first flow rate for a first period, the first flow rate is larger than the second flow rate, or the first period is longer than the second period.

Optionally, the first flow rate is 100 ml/min to 150 ml/min, and the second flow rate is 90 ml/min to 110 ml/min.

Optionally, a developing ability of the developer solution transmitted to the first area AA is greater than a developing ability of the developer solution transmitted to the second area BB.

Optionally, the developer solution transmitted to the first area AA is of the same type as the developer solution transmitted to the second area BB.

Optionally, specific steps of developing the photoresist layer 21 located in the second area BB include the following steps.

The photoresist layer 21 located in the second area BB is completely removed or partially removed.

Specifically, after cleaning of the second area BB, the first nozzle 24 is controlled to move above the second area BB, and the first nozzle 24 is controlled to spray the second dose of the developer solution 23 to the second area BB while the substrate is driven to rotate around the axis thereof. During development of the second area BB in this step, a removing condition of the photoresist layer 21 in the second area BB may be controlled by controlling the second dose of the developer solution 23 sprayed to the second area BB. For example, the photoresist layer 21 located in the second area BB may be sufficiently removed by increasing the second dose of the developer solution 23 sprayed to the second area BB; and the photoresist layer 21 located in the second area BB may be also partially removed by reducing the second dose of the developer solution 23 sprayed to the second area BB.

After the development of the second area BB first, the first nozzle 24 is moved to the position above a center of the first area AA. The first nozzle 24 is controlled to spray the first dose of the developer solution 23 to the first area AA while the substrate is driven to rotate around its axis, as shown in FIG. 2C. With rotation of the substrate, the developer solution will gradually flow from the first area AA to the second area BB under an action of centrifugal force, and finally is spread on the entire surface of the photoresist layer 21, as shown in FIG. 2D. Although the developing ability of the developer solution 23 in this step is gradually reduced as the developer solution keeps reacting with the photoresist layer 21 during the developer solution 23 is flowing, the residual photoresist layer 21 in the second area BB after the development can be reduced or even completely avoided during developing by spraying the developer solution to the center of the first area AA. Because the second area BB has been developed in advance and the photoresist layer 21 located in the second area BB has been partially (reference sign 25 in FIG. 2C represents residuals of the photoresist layer 21 remaining in the second area after development) or completely removed. Therefore, the uniformity of development of the photoresist layer 21 is improved, and uniformity of characteristic sizes during photolithography is improved, thereby reducing formation of defects, and ensuring performance of a semiconductor structure.

On the one hand, since the developer solution 23 sprayed to the first area AA will flow to the second area BB along with the rotation of the substrate, the photoresist layer 21 remaining in the second area BB will further be developed. On the other hand, the developer solution 23 sprayed to the first area AA diffuses in every direction with the rotation of the substrate. In order to ensure that the photoresist layer 21 in the first area AA is fully developed, in the specific example, the first dose of the developer solution 23 transmitted to the first area AA is set to be larger than the second dose of the developer solution 23 transmitted to the second area BB.

According to the specific example, by setting the first flow rate to be larger than the second flow rate and the first period to be larger than the second period, the first dose is ensured to be larger than the second dose, so that the photoresist layer 21 in the first area AA and the second area BB can be fully developed. For example, the first flow rate is 100 ml/min to 150 ml/min, the first period is 3 s to 5 s, the second flow rate is 90 ml/min to 110 ml/min, and the second period is 1 s to 3 s. Those of skill in the art may also set only the first flow rate to be larger than the second flow rate or only the first period to be larger than the second period according to actual needs. By adjusting the first flow rate, the first period, the second flow rate and the second period respectively, the uniformity of the development of the whole photoresist layer 21 can be ensured.

In the specific example, the developer solution transmitted to the first area AA and the developer solution transmitted to the second area BB may be the same (For example, they are both tetramethylammonium hydroxide), or may be different. In the specific example, the developer solution transmitted to the first area AA and the developer solution transmitted to the second area BB are the same, thereby simplifying the manufacturing process and reducing costs.

In other specific examples, the developer solution transmitted to the first area AA and the developer solution transmitted to the second area BB are different. For example, the developing ability of the developer solution transmitted to the first area AA is greater than the developing ability of the developer solution transmitted to the second area BB, so that the developer solution transmitted to the first area AA also can have a certain developing ability when flowing to the second area BB under the action of centrifugal force, and the photoresist layer 21 remaining in the second region BB can be completely removed.

Optionally, the method for improving uniformity of photoresist development further includes the following steps.

The substrate is driven to rotate around the axis thereof at a second rotating speed while the developer solution 23 is transmitted to the second area BB.

The substrate is driven to rotate around the axis thereof at a first rotating speed while the developer solution 23 is transmitted to the first area AA. The first rotating speed is larger than the second rotating speed.

Optionally, the second rotating speed is 50 rpm to 200 rpm, and the first rotating speed is 100 rpm to 300 rpm.

Specifically, the reason why the second rotating speed is set to be less than the first rotating speed is that when the developer solution 23 is only in the second area BB located at the edge, a too fast rotating speed will make the developer solution 23 to be directly thrown out of the surface of the photoresist layer 21, resulting in that the developer solution 23 cannot be tiled on the second area BB, thus affecting a developing effect of the second area BB.

Optionally, the first area AA is in a circular shape, and the second area BB is in an annular shape surrounding the first area.

The distance between an edge of a side of the second area BB towards the first area AA and the center of the first area AA is 80 mm to 120 mm, for example, 90 mm, 100 mm, 110 mm and the like.

In the specific example, the distance from the edge of the side of the second area BB towards the first area AA to the center of the first area AA is 80 mm to 120 mm, which can further ensure the development ability at the edge and achieve uniform development.

In the specific example, illustrated as an example, the entire photoresist layer 21 on the surface of the substrate is divided into two areas and the development is performed with two steps. Those of skill in the art also can, according to actual needs, divide the entire photoresist layer 21 into multiple areas, and the multiple areas are successively arranged along the direction from the center of the photoresist layer to the edge of the photoresist layer. For example, the entire photoresist layer 21 are divided into N (N is a positive integer greater than or equal to 3) areas, a first area located at the center of the photoresist layer 21 is circular, remaining (N−1) areas are annular, and the (N−1) annular areas are successively arranged along the direction from the center of the photoresist layer to the edge of the photoresist layer. A whole development process may be divided into N steps. First, the (N−1) annular areas are developed successively along a direction from the edge of the photoresist layer to the center of the photoresist layer. That is, a total of (N−1) times of development are performed. Then a developer solution is sprayed to the center of the first area, and the photoresist layer of the first area is developed. While developing the photoresist layer in the first area, the photoresist layer remaining in the (N−1) annular areas can be developed at the same time, so that the development of the entire photoresist layer is relatively uniform. In the specific example, the “multiple” means “more than or equal to three”.

Optionally, after developing the photoresist layer 21 located in the first area AA, the method further includes the following steps.

A cleaning fluid 26 is transmitted to a center of the first area AA, simultaneously the substrate is driven to rotate around an axis thereof, and removing the developer solution 23 remaining on a surface of the photoresist layer 21.

Optionally, during transmitting the cleaning fluid 26 to the center of the first area AA, the substrate rotates around its axis at a third rotating speed, and the third rotating speed is larger than the first rotating speed.

Specifically, the first nozzle 24 finishes spraying the developer solution 23 on the first area AA, the substrate is stationary for 30 s to 60 s to make the developer solution 23 fully reacted with the photoresist layer 21 to ensure complete development. Then, the cleaning fluid 26 is sprayed from a third nozzle 27 directly above a center of the substrate onto the surface of the substrate. With the rotation of the substrate, the cleaning fluid 26 infiltrates the entire surface of the substrate, and the developer solution 23 and development by-products remaining on the surface of the substrate are removed under the action of centrifugal force. In the specific example. In this specific example, the cleaning fluid 26 may be but is not limited to deionized water. The third rotating speed may be 500 rpm to 1000 pm, and the cleaning with the cleaning fluid 26 may last 6 s to 10 s.

Optionally, after removing the developer solution 23 remaining on the surface of the photoresist layer 21, the method further includes the following steps.

As shown in FIG. 2F, the substrate 28 is driven to rotate around its axis at a fourth rotating speed, and the cleaning fluid remaining on the surface of the substrate 28 is removed. The fourth rotating speed is larger than the third rotating speed.

Specifically, after removing the residual developer solution 23 and development by-products remaining, the substrate 28 is driven to rotate around its axis at a high speed (for example, the fourth rotating speed is 2500 rpm) for 15 s to 25 s (for example, 20 s) to throw out the residual cleaning fluid on the surface of the substrate 28 to ensure the surface of the substrate 28 to be dry and clean.

According to the method for improving the uniformity of the photoresist development provided by the specific example, through two development steps of firstly developing an edge area of the photoresist layer and then developing a center area of the photoresist layer, the problem of incomplete edge development caused by reduction of the developing ability in the process in which the developer solution flows from the center to the edge is avoided, the uniformity of overall development of the photoresist layer is ensured, the residual photoresist layer in the edge area is avoided, a smooth progress of subsequent manufacturing processes is ensured, and the performance of the semiconductor structure is improved.

The above is only the preferred example of the disclosure. It should be noted that, without deviating from the principles of the disclosure, a plurality of improvements and refinements may be made by those of ordinary skill in the art, and these improvements and refinements shall also be deemed as the claims of the disclosure.

What is claimed is:

1. A method for improving uniformity of photoresist development, comprising:
providing a substrate, wherein a surface of the substrate is coated with a photoresist layer, and the photoresist layer comprises a first area and a second area around a periphery of the first area;
transmitting a second developer solution to the second area, and developing the photoresist layer located in the second area; and
transmitting a first developer solution to the first area, and developing the photoresist layer located in the first area.

2. The method for improving uniformity of the photoresist development according to claim 1, wherein prior to the transmitting the second developer solution to the second area, the method further comprises:
cleaning the second area.

3. The method for improving uniformity of photoresist development according to claim 2, wherein said cleaning the second area comprises:
providing a second nozzle, and moving a spout of the second nozzle to a position above the second area; and
controlling the second nozzle to spray a cleaning agent to the second area to enable the cleaning agent to cover the photoresist layer located in the second area while driving the substrate to rotate around an axis of the substrate.

4. The method for improving uniformity of photoresist development according to claim 3, wherein the cleaning agent is deionized water.

5. The method for improving uniformity of photoresist development according to claim 1, wherein said developing the photoresist layer located in the second area comprises:
completely removing the photoresist layer located in the second area; or
partially removing the photoresist layer located in the second area.

6. The method for improving uniformity of photoresist development according to claim 1, further comprising:
providing a first nozzle for spraying the developer solution;
controlling the first nozzle to spray a second dose of the second developer solution to the second area, and developing the photoresist layer located in the second area; and
controlling the first nozzle to spray a first dose of the first developer solution to the first area, and developing the photoresist layer located in the first area, wherein the first dose is larger than the second dose.

7. The method for improving uniformity of photoresist development according to claim 6, wherein the first nozzle sprays the second developer solution to the second area at a second flow rate for a second period; and
the first nozzle sprays the first developer solution to the first area at a first flow rate for a first period, the first flow rate is larger than the second flow rate, and the first period is longer than the second period.

8. The method for improving uniformity of photoresist development according to claim 6, wherein the first nozzle sprays the second developer solution to the second area at a second flow rate for a second period; and
the first nozzle sprays the first developer solution to the first area at a first flow rate for a first period, the first flow rate is larger than the second flow rate, or the first period is longer than the second period.

9. The method for improving uniformity of photoresist development according to claim 7, wherein the first flow rate is 100 ml/min to 150 ml/min, and the second flow rate is 90 ml/min to 110 ml/min.

10. The method for improving uniformity of photoresist development according to claim 1, wherein a developing ability of the first developer solution is greater than a developing ability of the second developer solution.

11. The method for improving uniformity of photoresist development according to claim 1, wherein the first developer solution is of a same type as the second developer solution.

12. The method for improving uniformity of photoresist development according to claim 1, further comprising:
driving the substrate to rotate around an axis thereof at a second rotating speed while transmitting the second developer solution to the second area; and
driving the substrate to rotate around the axis thereof at a first rotating speed while transmitting the first developer solution to the first area, wherein the first rotating speed is larger than the second rotating speed.

13. The method for improving uniformity of photoresist development according to claim 12, wherein the second rotating speed is 50 rpm to 200 rpm, and the first rotating speed is 100 rpm to 300 rpm.

14. The method for improving uniformity of photoresist development according to claim 12, wherein after said developing the photoresist layer located in the first area, the method further comprises:
transmitting a cleaning fluid to a center of the first area, simultaneously driving the substrate to rotate around the axis thereof, and removing the first and the second developer solution remaining on a surface of the photoresist layer.

15. The method for improving uniformity of photoresist development according to claim 14, wherein during transmitting the cleaning fluid to the center of the first area, the substrate rotates around the axis thereof at a third rotating speed, and the third rotating speed is larger than the first rotating speed.

16. The method for improving uniformity of photoresist development according to claim 15, wherein the third rotating speed is 500 rpm to 1000 rpm.

17. The method for improving uniformity of photoresist development according to claim 15, wherein after said removing the developer solution remaining on the surface of the photoresist layer, the method further comprises:
driving the substrate to rotate around the axis thereof at a fourth rotating speed, and removing the cleaning fluid remaining on the surface of the substrate, wherein the fourth rotating speed is larger than the third rotating speed.

18. The method for improving uniformity of photoresist development according to claim 1, wherein the first area is located at a center of the photoresist layer; and
the second area is located at an edge of the photoresist layer and around the periphery of the first area.

19. The method for improving uniformity of photoresist development according to claim 1, wherein the first area has a circular shape, and the second area has an annular shape surrounding the first area; and
a distance between an edge on a side of the second area towards the first area and a center of the first area is 80 mm to 120 mm.

20. A method for improving uniformity of photoresist development, comprising:
providing a substrate, wherein a surface of the substrate is coated with a photoresist layer, the photoresist layer comprises N areas, an area located at a center of the photoresist layer is a first area having a circular shape, remaining (N−1) areas have annular shapes, the (N−1) annular areas are successively arranged along a direction from the center of the photoresist layer to an edge of the photoresist layer, and N is a positive integer greater than or equal to 3;
developing the annular (N−1) areas successively along a direction from the edge of the photoresist layer to the center of the photoresist layer; and
spraying a developer solution to the center of the first area, and developing the photoresist layer of the first area.
